(19) United States
(12) Patent Application Publication
(10) Pub. No.: US 2002/0162685 A1
(43) Pub. Date: Nov. 7, 2002

(54) Thermal dissipating printed circuit board and methods

(76) Inventors: Jeffrey Gotro, Trabuco Canyon, CA (US); Karim Fernandes, Alta Loma, CA (US)

Correspondence Address: Robert D. Fish, 611 Anton Blvd., Suite 1400, Costa Mesa, CA, 92626, US

(21) Appl. No.: 10/143,713

(22) Filed: May 7, 2002

Related U.S. Application Data
(60) Provisional application No. 60/289,505, filed on May 7, 2001.

(51) Int. Cl. H05K 1/03; H05K 3/30; H05K 3/20

(52) U.S. Cl. 174/258; 174/256; 174/250; 29/831; 29/846; 29/841

(57) ABSTRACT

A multilayer circuit board comprising at least one substantially void free encapsulated heavy copper core and methods for producing such a board. Such a board may be formed by providing a first core that includes a substrate and heavy copper circuit traces, filling the spaces between circuit traces with a resin, and at least partially curing the resin so as to form two exposed and substantially planar surfaces on opposite sides of the core. The filled and planarized core is then laminated with additional dielectric layers to form a fully cured, void free multilayer printed circuit board.

This application claims the benefit of U.S. provisional application No. 60/289505 incorporated herein by reference in its entirety.

### FIELD OF THE INVENTION

The field of the invention is circuit board fabrication. More particularly, the field is the fabrication of multi-layer circuit boards having improved thermal spreading capabilities and thermal conductivity.

### BACKGROUND OF THE INVENTION

The current state of the art in multilayer circuit board fabrication involves building a structure containing two or more layers of patterned conductive sheets (typically copper) insulated from each other by a polymeric dielectric. The dielectric is typically a high performance fiberglass reinforced epoxy resin.

Formation of a multilayer circuit board typically starts with the circuitization of copper clad laminate cores using well-established lithographic techniques (print and etch). The laminate cores are generally fully cured (C-staged) fiber reinforced resin covered with a copper foil. The thickness of the core and thickness of the copper can be tailored for the particular type of circuit board. Multilayer circuit boards will often comprise two or more circuitized cores laminated together.

Lamination of the cores to form multilayer boards is often accomplished by placing B-staged prepreg (partially cured epoxy resin impregnated into a woven fiberglass fabric) between the circuitized cores and laminating the resulting stack-up using heat and pressure. The B-staged prepreg serves two purposes; first, as a source of resin to flow into and between the circuit traces and secondly, as an adhesive to bond the circuitized cores together. Multilayer boards can have 4 layers (two dual-sided circuitized cores) to greater than 40 layers of circuitry. The process is similar regardless of the number of layers.

As an example, FIG. 1A is a perspective view of a typical printed circuit board 1 with external wiring lines 4 and embedded power/ground (or voltage) planes 2. Interconnections are made from front to back and to internal planes by means of plated-through-holes (PTH) 3. The plated-through-holes are spaced apart by the grid spacing 5 to allow for the wiring lines to pass in between. The wiring lines make connections to the edge of the board by means of pads 6.

The multilayer structure in FIG. 1a may be fabricated by a layup process and subsequent lamination under heat and pressure using a prescribed heating rate and pressure profile. As shown in FIG. 1B, the lamination “layup” consists of external copper layers 7. Layers 7 are circuitized into the external wiring lines after lamination, drilling, and plating. The internal power/ground planes 2 are circuitized using standard lithographic methods. The power/ground core 2 is typically made using FR-4 epoxy laminate cores and may contain copper in thickness ranging from 0.0005″ (½ oz) to 0.014″ or greater. A dielectric layer (called a prepreg) 8 is used to insulate the power/ground 2 planes from the circuit traces. Additionally, the prepreg layer 8 is used to provide resin to fill into the spaces in the power/ground plane 2. During lamination, the prepreg layer 8 softens and flows, resulting in a fully consolidated, high performance laminate.

The B-stage prepreg acts as a fill material in that, during the lamination process, it softens, flows, and fills in between the circuit features. The key to the lamination process is that the B-staged prepreg contains enough resin to flow and encapsulate all of the circuit traces. If the resin content is too low, or the lamination process is not optimized, voids can occur in the final product. The lamination process also causes the thermosetting polymer to fully cure leading to a solid high performance multilayer structure. When standard copper thicknesses are used (typical thickness is in the range of 0.0005″ to 0.004″) the lamination process can be optimized to provide adequate flow and resin to fill the core.

For special applications requiring the dissipation of large amounts of heat for an electronic component (for example a power supply), the multilayer printed circuit board incorporates power/ground planes with increased copper thickness. The increased thickness provides an enhanced path for heat spreading and dissipation. The copper thickness in standard circuit boards is in the range of ½ ounce to 2 ounce (0.0007-0.0028″). For copper thickness up to 0.004″, the standard lamination method is generally adequate to fill between the traces without forming voids and does not significantly increase the spacing between the power/ground layers and signal layers.

Voids are very detrimental to the functionality of the circuit board due to the propensity to form shorts after subsequent processing (such as drilling and plating to form interconnecting vias). When the copper thickness increases to greater than 0.004,″ it becomes increasingly difficult to laminate enough resin into the cavities between the traces using standard prepregs. One method to fill the cavities in thick copper planes is to use multiply plies of prepreg with high resin content. While this may lead to adequate filling of the circuit features, using multiple prepreg sheets causes an increase in the dielectric spacing and an undesirable increase in the overall circuit board thickness. Additionally, the addition of prepreg causes degradation in the thermal performance, since the dielectric is an insulating material. Due to the large and deep areas that require filling, it is likely that voids form in the filled areas. During conventional lamination, the large amount of resin flow required to fill into the spaces between the traces may also lead to thickness variations across the circuit board.

Unfortunately, known methods are generally insufficient to provide for fully cured void-free resin between all circuit traces on a 0.004″ (or higher) copper etched power/ground core and thus insufficient to allow thicker copper power/ground planes that would enhance the heat spreading ability of the multilayer structure.

### SUMMARY OF THE INVENTION

The present invention is directed to a thermal dissipating printed circuit board and methods for manufacturing such a board. In particular, means to fill between circuit features with either a high Tg thermally enhanced dielectric or a non-thermally enhanced resin system are disclosed. The resin systems are solventless (no organic solvents are used to dissolve the resin components) allowing the use of hot melt resin dispensing systems.

In the preferred embodiment, a solventless hot melt resin system with high thermal conductivity (>5 W/m-° K) is applied to the circuitized core by means of a slot die extrusion head. The resin system is heated in a hot melt dispensing system, pumped into a precision machined manifold and extruded through a thin opening (slot die) onto the moving panel. The circuitized core moves past the opening of the slot die allowing the dielectric material to flow onto the surface and into the spaces between the traces. The volume of material dispensed onto the core is controlled by the pump speed, the die width (slot width), and line speed. By optimizing these three control variables, a precise amount of dielectric can be placed on the circuitized cores. Subsequently, an additional leveling operation can be added using a doctor blade or rubber squeegee to provide uniform thickness of the dielectric across the width of the panel. Additionally, a heated roller can be applied to the surface of the coated core with slight pressure to achieve a uniform thickness of dielectric across the core.

After the dielectric is applied and leveled, the cores are passed through a heated oven to lower the viscosity allowing air bubbles to escape and causing the resin to partially cure (or B-stage). The resin does not need to be dried, as is the case for typical solvent-based B-stage resins, but additional curing will reduce the tackiness of the dielectric. The core must not be tacky (or sticky) after the application of the dielectric since the panel needs to be coated on the second side after the first side is coated. The preferred embodiment uses an infrared (IR) heating source to heat the liquid resin system and cause a partial cure. Additionally, conventional hot air (forced convection) heating can be used to provide heating and curing of the resin. The dielectric resin system will be fully cured (attain the final fully cured properties) during the subsequent lamination process used to incorporate the coated circuitized core into the multilayer structure.

It is contemplated that filling the spaces between circuit features as a step separate from that of laminating cores together provides for a desirable balance between thermal conductivity characteristics and multi-layer thickness. This is particularly true when filling involves the formation of at least partially cured, substantially planar surfaces on a circuitized core.

Thermally enhanced dielectrics (including prepreg and non-supported resins) having thermal conductivities >5 W/m-° K are preferred for use in the filling process previously described. In the preferred embodiment, the coating resin consists of a solventless formulation of epoxy resins, curing agents, accelerators, and fillers. The epoxy resins provide the required physical properties. Additionally, thermosetting resins such as cyanate esters, and polyimides can also be utilized. The curing agent helps crosslink and forms the desired network structure and achieves the desired glass transition temperature (Tg). Fillers (typically boron nitride, aluminum oxide, aluminum nitride, or other similar high thermal conductivity, electrically insulating fillers) are incorporated into the thermosetting resin to improve the thermal conductivity. The use of solvents is avoided for both ease of handling, environmental, and worker safety concerns. Additionally, the resin system is flame retardant allowing a UL flammability rating of 94-V0. Resins used in multilayer printed circuit boards must achieve the UL flammability rating.

It is contemplated that the materials, devices, and methods disclosed herein will:

(a) provide multilayer circuit boards with enhanced heat spreading performance without increasing the overall board thickness;

(b) provide multilayer circuit boards incorporating heavy copper power/ground planes (greater than or equal to 2 ounce copper) without increasing the overall board thickness, leading to enhanced ability of the board to dissipate and conduct heat away from components mounted on the circuit board;

(c) provide multilayer circuit boards with reduced dielectric spacing between the heavy copper power/ground planes, leading to a multilayer circuit board with decreased overall thickness and improved thermal spreading and thermal conductivity;

(d) provide multilayer circuit boards with increased resistance to direct current (DC) dielectric breakdown (HIPOT testing);

(e) provide a means to produce void-free encapsulated heavy (thick) copper power/ground planes; and

(f) provide a means to manufacture a void-free multilayer printed circuit board.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1a shows a typical multilayer printed circuit board with two internal power/ground (or voltage) planes.

FIG. 1b shows the multilayer stack-up prior to lamination for the typical multilayer printed circuit board shown in FIG. 1a.

FIG. 2 is a cutaway side view of a circuit board embodying the invention.

FIG. 3 is a cutaway side view of a core of FIG. 2.

FIG. 4 is a schematic of a method embodying the invention.

FIG. 5 shows a filling system that is part of a filling process for a thick heavy copper circuitized power/ground plane.

FIG. 6 shows a close up of the filling system of FIG. 5.

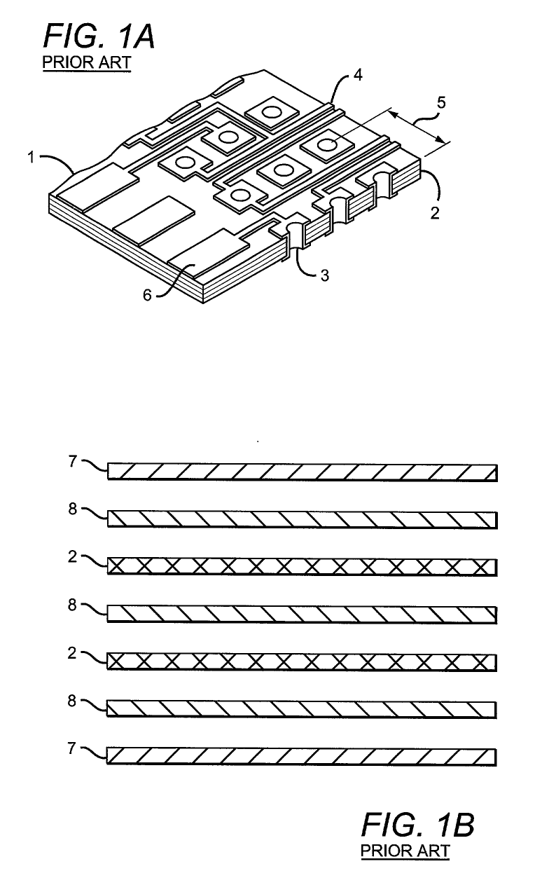

### DETAILED DESCRIPTION

Multilayer Circuit Board

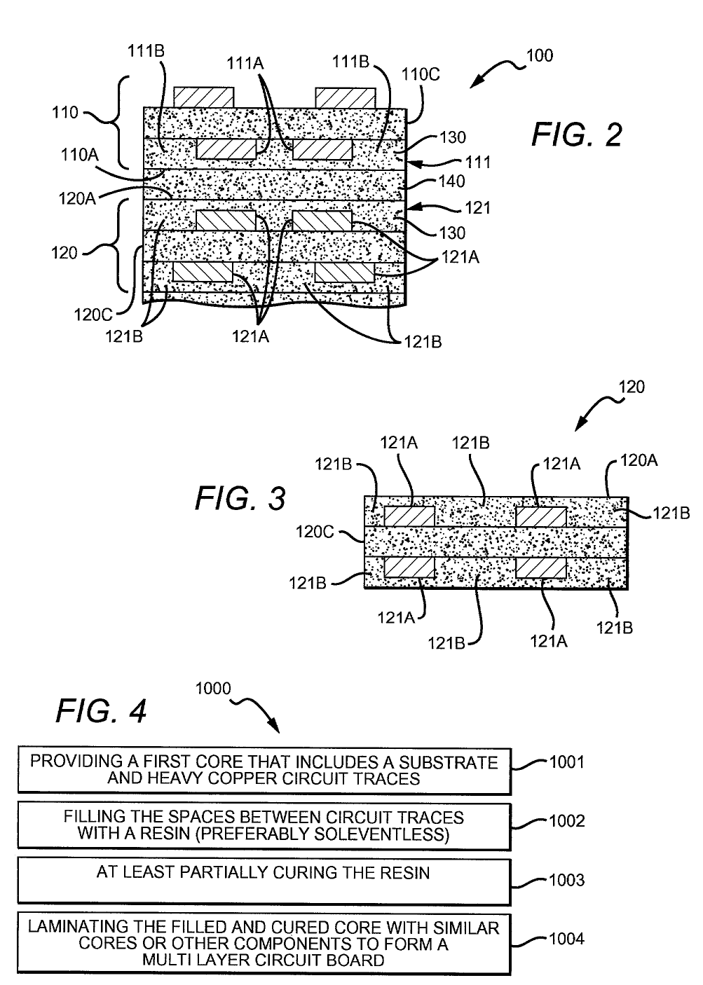

Referring to FIGS. 2 and 3, a multilayer circuit board 100 comprises cores 110 and 120. Cores 110 and 120 each comprise internal circuitized heavy copper planes 111 and 112, with each plane comprising traces (111A and 121A) and spaces (111B and 121B). The traces (111A and 121A) each comprise at least 0.003″ thick copper. Spaces 111B and 121B are filled with an at least partially cured, substantially void free resin 130. Cores 110 and 120 are coupled together by dielectric layer 140 adhering to planar surfaces 110A (formed at least partially by resin 130 in spaces 111B) and 120A (formed at least partially by resin 130 in spaces 121B). Prior to lamination, planar surface 110A and 120A are exposed surfaces of cores 110 and 120. FIG. 3 shows core 120 prior to lamination into circuit board 100. After lamination, traces 111A and 121A are separated at least by the cured dielectric layer 140, and preferably by resin/fill material 130 overlying traces 111A and 121A. The amount of separation between traces 111A and 121B is referred to as the “dielectric spacing”.

The phrase “heavy copper” as used herein indicates copper having a thickness of at least 3 mils (0.003″). The phrase “void free” is used to indicate that there are no visible voids having a diameter larger than 5 microns. The phrase “planar surface” is used to indicate that the distance between any point on such a surface and the closest point on an imaginary reference plane is within an acceptable range. Herein, a “planar” surface has a surface variance of less than 3 mils (i.e. the difference in the distance between any first point on such a surface and the closest point on an imaginary reference plane, and any second point on such a surface and the closest point on the same imaginary reference plane is less than 3 mils), more preferably less than 2 mils or 1 mil, and most preferably, less than one half of a mil (0.5 mils).

It is also preferred that, while minimizing the dielectric spacing, the dielectric material separating traces 111A and 121A (i.e. any portion of resin 130 covering traces 111A and/or 121A along with dielectric layer 140) has a thermal conductivity greater than or equal to 5 W/m-° K, and a dielectric breakdown voltage of at least 1500 V/mil. Although the amount of dielectric spacing will vary at least in part based on the thickness of traces 111A and 121A, and on the type of materials used for resin 130 and layer 140, circuit board 100 can be characterized by the ratio of copper thickness to the dielectric spacing between the traces 111A and 121A. Using previously known methods that ratio would generally be far less than 1 (i.e. the dielectric spacing is usually substantially greater than the copper thickness). For the disclosed board and methods, that ratio will be at least 1 (i.e. the dielectric spacing will be less than or equal to the copper thickness.) For convenience, that ratio will be referred to herein as the thickness-separation (“TS”) ratio.

Method of Forming a Multi-Layer Circuit Board

Referring to FIG. 4, a multi-layer circuit board may be formed by process 1000 comprising the following: step 1001, providing a first core that includes a substrate and heavy copper circuit traces; step 1002, filling the spaces between circuit traces with a resin (preferably solventless); and step 1003, at least partially curing the resin. Once such a core is formed it can be laminated (step 1004) with similar cores or other components to form a multi-layer circuit board. If two cores are to be used, it is preferred that the second core be similar to the first core, and the dielectric spacing between traces of the cores after they are laminated together be less than 0.004″, or, more preferably, less than or equal to 0.002″. It is also preferred that the thickness-separation ratio be at least 1, and more preferably at least 1.4.

Lamination of the first and second cores typically involves sandwiching one or more at least partially cured dielectric layers between the first and second cores. Lamination will often be preceded by planarization of the surface formed by the resin fill material and possibly the traces if the fill material does not cover the traces.

This method may be used to form cores 110 and 120 and multi-layer circuit board 100 of FIGS. 2 and 3. In such a case, multi-layer circuit board 1 may be formed by providing core 110 having substrate 110C and heavy copper traces 111A; filling spaces 111B between traces 111A with resin 130; and partially or fully curing resin 130. Core 120 may be formed in a similar fashion. For the sake of clarity, further discussion of the method in its various embodiments will, at times, be discussed as if core 120 and multi-layer circuit 100 of FIGS. 2 and 3 are being formed. However, the disclosed methods are likely suitable for the formation of cores and circuit boards other than those shown herein. Where applicable, it is preferred that any circuit boards formed using the foregoing method will have the same preferred physical characteristics as those given herein for circuit board 1 (i.e. thickness-separation ratio, dielectric breakdown voltage, etc.).

It is contemplated that in some embodiments resin 130 will, in addition to filling the spaces 111B and 121B between traces 111A and 121A, at least partially cover traces 111A and 121A. Covering traces 111A and 121A has the advantage, among others, of permitting planarization of resin 130 to form planar surfaces 110A and 110B with less risk of damage to or undo thinning of traces 111A and 121A.

It should be noted that some embodiments might utilize a standard, non-thermally enhanced resin as resin 130. Similarly, dielectric 140 may comprise a standard, non-thermally enhanced, prepreg. Non-thermally enhanced in either case indicates that the resin and/or prepreg may have a thermal conductivity that is as low as 0.5 W/m-° K). Alternatively, other embodiments may utilize a combination of non-thermally enhanced and thermally enhanced resis and/or prepregs.

In still other alternatives, resin 130 may comprise a photo-curable resin in which partial curing/B-staging is accomplished through the use of ultra-violet (UV) or other light. Doing so may comprise coating a panel with a photo-curable resin, exposing the filled panel to UV light, partially curing the panel, and subsequently performing standard lay-up and lamination steps to obtain a fully cured multi-layer. Photo-curable resins may be epoxy or acrylate based, include appropriate UV initiator and catalysts, and be solvent-less or solvent based.

It is contemplated that a benefit of using the method described above is that it makes possible the formation substantially void free encapsulated heavy copper cores, the use of which, in turn, makes possible the formation of multi-layer circuit boards wherein the ratio of copper thickness to the dielectric spacing between the heavy copper planes is at least 1.4 while maintaining the preferred core thermal conductivity and dielectric breakdown voltage.

Core Formation

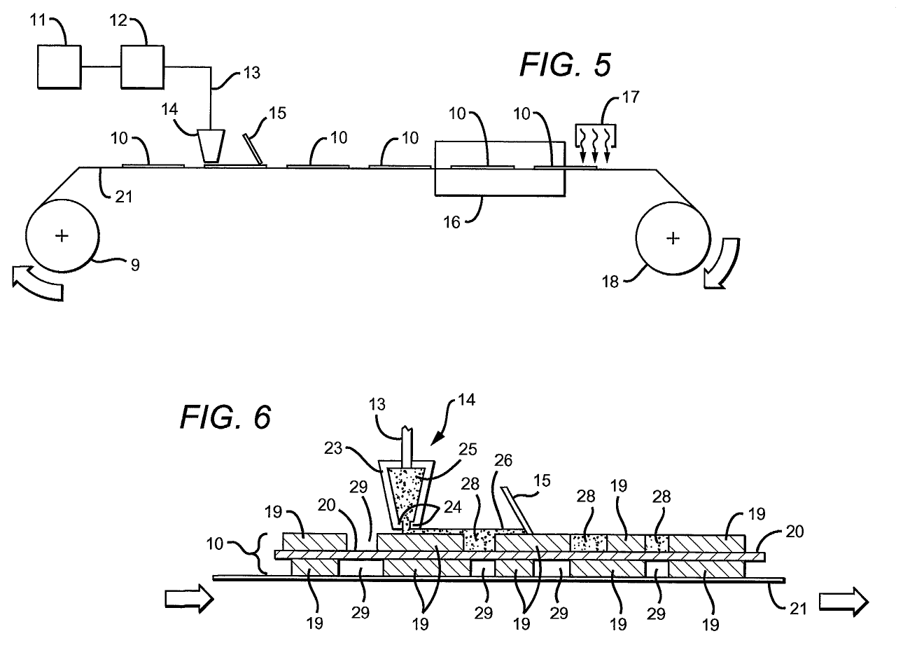

FIGS. 5 and 6 helps illustrate the coating/application process in which a circuitized heavy copper core is processed to form a core such as core 120 of FIG. 3. A solventless resin 25 is preferably contained in temperature controlled reservoir 11 and pumped into the dispensing system via a thermostatically controlled hot melt pumping device 12. The transfer line 13 from the hot melt system is thermostatically controlled to maintain the dielectric at the proper temperature during the transfer to the slot die dispensing head 14 which is precision machined and includes an adjustable outflow slot. The dielectric material 25 is extruded onto the circuitized power/ground plane 10 as it moves under the lips 24 of the extrusion die/dispensing head 14. A doctor blade or rubber squeegee 15 is used to level and ensure a uniform coating of dielectric 25 into the spaces 29 between the heavy copper planes. The dielectric 25 is in the liquid state as it emerges from the slot die extrusion head 14. An infrared oven 16 is used to at least partially cure (B-stage) the dielectric to ensure that the encapsulated and fully filled power/ground planes 10 are not sticky (tack-free). The B-staging oven may also have hot air convection to aid in the partial curing of the coated dielectric. After the partial curing in the B-stage oven 16 the filled heavy copper power/ground planes 10 are cooled using an air impingement system 17. The high flow air curtain cools the dielectric allowing the operator to unload the panels at the end of the line.

The circuitized power/ground plane/core 10 consists of a FR-4 epoxy laminate base 20 with heavy copper 19 (greater than or equal to 0.003″) circuitized on each face of the FR-4 epoxy base 20. During the power/ground core circuitization process, copper is etched away leaving open spaces 29 on the surface of the power/ground core 10.

The circuitized power/ground planes with heavy copper 10 are loaded onto the moving web/release liner 21. The disposable release liner 21 serves two purposes, one is to provide a moving web to carry the panels through the process, and secondly, the liner serves to capture excess dielectric during the coating process. The liner is disposable, is typically provided from a source roll 9, and is accumulated on a take-up roll 18 at the end of the process.

The extrusion die lips 24 are adjustable to control the amount/thickness of the dielectric layer being extruded onto the moving circuitized power/ground 10 planes. The coated weight is controlled by a combination of controlling the speed of pump 12, the line speed of the release liner 21 and the width of the slot die lips 24. The dielectric is extruded onto the surface of the moving power/ground core/plane 10 forming a thin layer 26 on the top surface and filling the open spaces 29 with material 28.

A doctor blade or rubber squeegee 15 is used to evenly dispense the hot melt dielectric into the spaces and wipe the excess dielectric from the surface of the panel. The extruded thin film of hot melt dielectric 26 does not need to be completely removed from the surface of the heavy copper, since the core will be laminated into a multilayer printed circuit board using prepreg in a subsequent lamination process. After the leveling process using the squeegee or doctor blade 15, the areas between the circuit traces are uniformly and completely filled and void-free as shown by filled spaces 28.

The process described here coats the circuitized power/ground planes 10 on one side only. This leaves open areas 29 on the back of the panel between the heavy copper circuit features 19. After the first surface is filled, the panel is reloaded into the front of the process and the second surface is coated during a second pass.

It should be noted that alternative systems may use different mechanisms for obtaining relative movement between a fill head and a core being filled such as by moving the head relative to an at least momentarily stationary core.

Thus, specific embodiments and methods for forming improved thermal dissipating circuit boards having improved thermal have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A method of forming a multilayer circuit board comprising:
providing a first core that includes a substrate and heavy copper circuit traces;
filling the spaces between circuit traces with a resin; and
at least partially curing the resin so as to form two exposed and substantially planar surfaces on opposite sides of the core.

2. The method of claim 1 wherein both of the two substantially planar surfaces is separated from a surface of the heavy copper circuit traces by less than 2 mils.

3. The method of 2 wherein the resin used to fill the spaces also covers the traces, and the at least partial curing of the resin occurs while the resin filling the spaces and covering the traces forms an exposed surface of the core.

4. The method of 3 wherein the dielectric breakdown voltage of the resin covering the traces is at least 1500 V/mil, and the cured resin has a thermal conductivity of at least 0.5 W/m-° K.

5. The method of 3 wherein the circuit traces comprise at least 0.005″ thick copper.

6. The method of 3 wherein the thickness of the first core varies less than 0.001″ across the entire core.

7. The method of 1 wherein the is photo-curable, and at least partially curing the resin comprises exposing the resin to ultraviolet light and subsequently baking the first core.

8. The method of 3 further comprising:
providing a second core that includes a substrate and heavy copper circuit traces and
has cured resin filling spaces between and covering the traces;
laminating the first core to the second core such that the distance between the cores is less than 0.004″.

9. The method of 8 wherein the distance between the cores is less than 0.002″.

10. The method of 8 wherein laminating the first core to the second core comprises sandwiching one or more at least partially cured dielectric layers between the first and second cores.

11. The method of claim 10 wherein the ratio of copper thickness to the dielectric spacing between the traces of the first and second core is at least 1.

12. The method of claim 11 wherein the ratio of copper thickness to the dielectric spacing between the traces of the first and second core is at least 1.4.

13. The method of 12 wherein the number of sandwiched dielectric layers is 1 or 2.

14. A core comprising circuit traces and spaces with the spaces being filled with an at least partially cured, substantially void free resin wherein the circuit traces comprise at least 0.003″ thick copper, and wherein the traces and filled spaces form an exposed planar surface.

15. The core of 14 wherein the exposed planar surface has a surface variance of less than X mils where X is one of 3, 2, 1, and 0.5.

16. A multilayer circuit board comprising at least one substantially void free encapsulated heavy copper core.

17. The circuit board of claim 16 further comprising at least two heavy copper planes separated by a dielectric layer having a thermal conductivity of at least 2 W/m-° K, and a dielectric breakdown voltage of at least 1500 V/mil, wherein the ratio of copper thickness to the dielectric spacing between the heavy copper planes is at least 1.4.

18. The board of claim 17 wherein the thickness of the copper planes is at least 0.005″.
